(19) United States
(12) Patent Application Publication
(10) Pub. No.: US 2007/0216015 A1
(43) Pub. Date: Sep. 20, 2007

(54) Integrated Circuit Chip With Electrostatic Discharge Protection Device

(75) Inventors: Wolfgang Schnitt, Norderstedt (DE); Hans-Martin Ritter, Nahe (DE)

Correspondence Address: PHILIPS ELECTRONICS NORTH AMERICA CORPORATION;INTELLECTUAL PROPERTY & STANDARDS, 370 W. TRIMBLE ROAD MS 91/MG, SAN JOSE, CA, 95131, US

(73) Assignee: KONINKLIJKE PHILIPS ELECTRONICS N.V., Eindhoven (NL)

(21) Appl. No.: 10/587,596

(22) PCT Filed: Jan. 20, 2005
(86) PCT No.: PCT/IB05/50241

§ 371 Date: Apr. 24, 2007

(30) Foreign Application Priority Data
Jan. 30, 2004 (EP) 04 100 342.7

(51) Int. Cl. H01L 21/44; H01L 23/60

(52) U.S. Cl. 257/692; 438/597; 257/E21.476; 257/E23.01

(57) ABSTRACT

Consistent with an example embodiment, in integrated circuit chip includes an electrostatic discharge (ESD) protection device. A feature of the ESD protection device includes a pair of spaced center and circumferential electrodes, the center electrode being formed by the first electrically conductive layer and the circumferential electrode being formed by the second electrically conductive layer, said electrodes being separated by a steroidal spark gap cavity.

The present invention relates to the field of integrated circuit chips, particularly to the protection of integrated circuit chips from electrostatic discharges.

Electrostatic discharge (ESD) refers to the phenomenon of electrical discharge of high current for a short duration. Electrostatic discharge (ESD) is known to degrade or destroy discrete devices such as transistors, diodes, inductors, capacitors and resistors in integrated circuits. Both voltage and current spikes can break down the dielectric or doped regions in various portions of individual semiconductor devices, thus rendering the entire device or even the entire chip completely or partially inoperable.

For ICs a major source of exposure to electrostatic discharge is formed by the charged human body (“Human Body Model”, HBM). The discharge of the human body generates peak currents of several amperes to the IC for about 100 ns.

A second source of electrostatic discharge is formed by metallic objects (“machine model”, MM); it can generate transients with significantly higher rise times than the HBM electrostatic discharge source.

A third source is described by the “charged device model” (CDM), in which the IC itself becomes charged and discharges to ground in the opposite direction than the HBM and MM electrostatic discharge sources.

Electrostatic discharge phenomena in ICs are growing in importance as the demand for higher operating speed, smaller operating voltages, higher packing density and reduced cost drives towards a reduction of all device dimensions. This generally implies thinner dielectric layers, higher doping levels with more abrupt doping transitions, and higher electric fields, which are all factors that contribute to an increased sensitivity to damaging electrostatic discharge events.

Conventional means for dealing with relatively small overvoltages include shunting capacitors, breakdown diodes, varistors and inductive coils. Breakdown diodes such as Zener diodes, when reverse biased beyond a certain threshold voltage, conduct large currents. Like virtually all overvoltage protection devices, such a diode is placed ahead or “upstream” of or in parallel with a circuit element to be protected, and shunts excess voltage applied there across to a discharge path such as a neutral line, D.C. common line, chassis or ground. However, such diodes are capable of handling only limited overvoltages without becoming permanently damaged themselves.

Spark gaps are another form of overvoltage protection associated with higher power devices, and recently miniaturized forms of them have been developed for use on P.C. boards and the like. Spark gaps contain two opposing electrodes separated by a nonconductive gas, such as air, which has a desired breakdown, or sparking voltage.

When an overvoltage is applied across the spark gap, the nonconductive gas becomes ionized, forming a relatively low resistance path between its electrodes.

Spark gaps provide electrostatic discharge protection with little or no added capacitance, but are difficult to implement on semiconductor chips and pose potential contamination and therefore reliability problems.

GB 2334627 discloses a spark gap assembly suitable for use in electronic circuits, comprising: a first at least partially conductive layer, a second at least partially conductive layer, nonconductive material positioned between said first layer and said second layer maintaining a vertically spaced relationship there between; at least one opening in at least one of said first layer and said second layer, said nonconductive material, when removed from said layer, having said at least one opening, whereby a vertical gap is formed between and communicates with each of said layers.

Such a vertical gap is an open space and may cause effects caused by humidity or variations in gas density, which can reduce the efficiency of the over-volt protection.

It is therefore an object of this invention to provide an improved integrated circuit chip comprising an integrated circuit and an electrostatic discharge protection device suitable for electrostatic discharge protection in the integrated circuit chip, that does not create a reliability problem.

According to the invention there is provided an integrated circuit chip comprising an integrated circuit and an electrostatic discharge device suitable for inclusion in an electrical circuit so as to provide electrostatic discharge protection.

An integrated circuit chip according to the invention comprises, in sequence, a substrate layer of a substrate material, an insulating layer of an insulating material, a first electrically conductive layer of a first electrically conductive material, a dielectric layer of a dielectric material and a second electrically conductive layer of a second electrically conductive material, said IC chip comprising at least one integrated circuit and at least one integrated electrostatic discharge protection device, said electrostatic discharge protection device comprising a pair of spaced center and circumferential electrodes, the center electrode being formed by the first electrically conductive layer and the circumferential electrode being formed by the second electrically conductive layer, said electrodes being separated by a teroidal spark gap cavity, wherein the toroid of the teroidal spark gap cavity comprises a base layer formed by the insulating layer of the integrated circuit chip, a side wall formed by the circumferential electrode, a cover layer formed by the dielectric layer of the integrated circuit chip, and the center of the toroid being formed by the center electrode comprising a contact pad in contact with the insulating layer, said electrostatic discharge protection device also comprising means to electrically connect the center electrode to input circuit paths to be protected from electrostatic discharge and means to electrically connect the circumferential electrode to an electrostatic discharge path comprising either a connection to a circuit ground or a circuit supply voltage.

Such an electrostatic discharge protection device is able to protect an integrated circuit against static discharge by passing large currents in a short time in a non-destructive manner.

The device structure provides excellent electrical performance, mechanical stability and high reliability. The electrostatic discharge protection device, when inserted into the integrated circuit chip to be protected, does not impose undue insertion losses in the circuit, nor decreases switching speeds or bandwidth by adding significant amounts of capacitance.

As an electrostatic discharge protection device of the present invention is deposited directly on top of an existing electronic circuit chip and connected thereto so as to provide overvoltage protection to a circuit present thereon, the devices of the present invention can be economically made as an integral part of IC chips by the chip manufacturer.

In addition, the electrostatic discharge device is mounted on the integrated circuit chip without taking up an excessive amount of space for installation of the electrostatic discharge device, thus meeting the recent trend of compactness, lightness and smallness of the apparatus.

The integrated circuit chip may further comprise a passive component selected from the group comprising resistors, capacitors, and inductors.

Within the integrated circuit chip, the first electrically conductive material may be polysilicon.

Within the integrated circuit chip, the second electrically conductive material may be aluminum.

Within the integrated circuit chip the spark gap cavity may contain a noble gas for reducing the breakdown voltage of the electrostatic discharge protection device.

As the gap is sealed off from the environment, it is not limited to an air gap. In one embodiment of the invention the gap is substantially filled with a gas which comprises an inert gas such as one of the noble gases e.g. argon. In this manner, the breakdown voltage of the gap under electrostatic discharge can be reduced and the device may benefit from an even more stable-rated breakdown voltage.

Within the integrated circuit chip the substrate material may be selected from the group comprising silicon, glass and a ceramic material.

The invention also provides a method of producing an integrated circuit device comprising an integrated circuit and an electrostatic discharge protection device, including the steps of a) providing a semiconductor substrate, b) depositing an insulating layer on the semiconductor substrate, c) depositing a first electrically conductive layer of a first electrically conductive material on said insulating layer, d) depositing a dielectric layer of a dielectric material on said first electrically conductive layer, e) etching spaced contact windows for a center electrode and a circumferential electrode, f) depositing a mask, g) etching a hollow groove into the first electrically conductive layer under the circumference of the contact window of the circumferential electrode, h) depositing a layer of a second electrically conductive layer through the contact window of the center electrode to mechanically contact the insulating layer, and through the contact window of the circumferential electrode to electrically contact the first electrically conductive layer, i) connecting the center electrode to input circuit paths to be protected from electrostatic discharge and connecting the circumferential electrode to an electrostatic discharge path comprising either a connection to a circuit ground or a circuit supply voltage.

The fabrication method is simple, yet flexible enough for different semiconductor product families and a wide spectrum of design and process variations. This innovation can be accomplished without extending production cycle time, and by using the installed equipment, so that no investment in new manufacturing machines is needed.

The invention will now be described by way of example with reference to the accompanying drawing, in which:

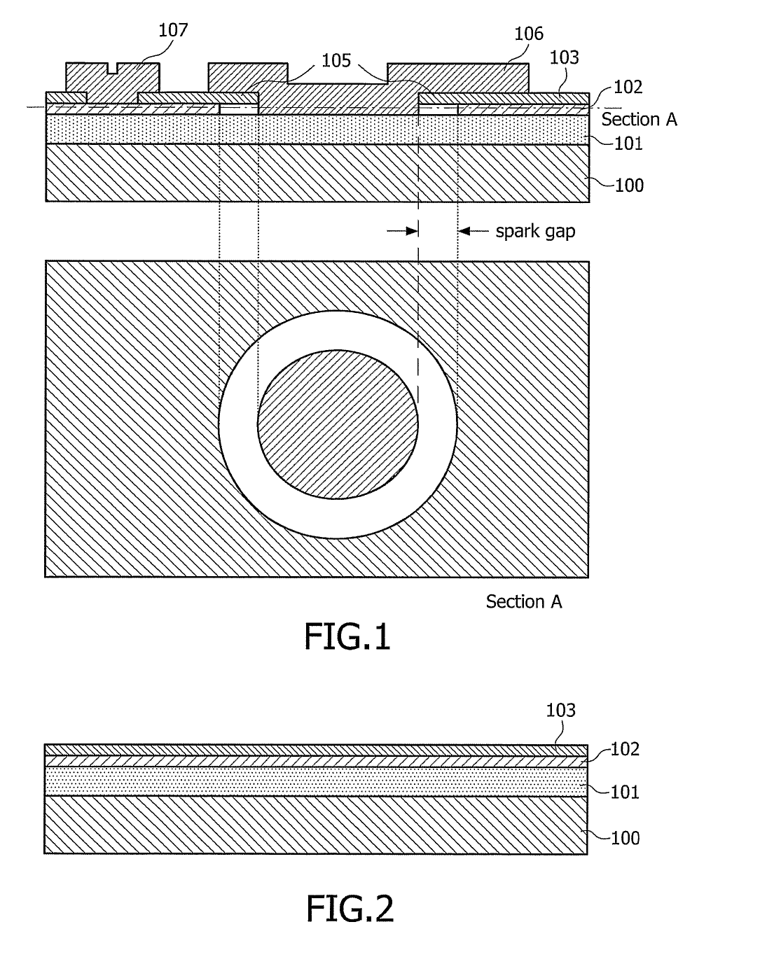

FIG. 1 shows a sectional side view and plan view of an integrated circuit according to the present invention equipped with an electrostatic discharge protection device.

FIGS. 2 to 6 show, in cross-section, details of an integrated circuit according to the invention equipped with an electrostatic discharge protection device, said Figures illustrating the production of a electrostatic discharge protection device.

The present invention is concerned with an integrated circuit chip comprising an integrated circuit sensitive to electrostatic discharge, positioned in close proximity to an electrostatic discharge protection device, the electrostatic discharge protection device being electrically connected to the electrostatic discharge-sensitive device.

Integrated circuits, especially for radio frequency (RF) applications require both active and passive elements. Active elements include metal-oxide-silicon field-effect-transistors (MOSFETs) and bipolar transistors. In RF CMOS (complimentary-metal-oxide-silicon), active elements include N-channel MOSFETs and P-channel MOSFETs. In RF silicon BiCMOS (bipolar-CMOS) technology, active elements include silicon bipolar junction transistors (BJT) in addition to CMOS MOSFETs. In silicon germanium (SiGe) technology, active elements include hetero-junction bipolar transistors (HBT.). Examples of passive elements include resistors, capacitors and inductors.

At least a portion of the semiconductor devices contained within integrated circuit chips is sensitive to electrostatic discharge.

An integrated circuit chip comprises a substrate 100, on which are successively deposited a layer of insulation material, a first layer of electrically conductive material, a layer of dielectric material and a second layer of a second electrically conductive material.

The material of the substrate may be any poly- or monocrystalline semiconducting material including, but not limited to, silicon, a silicon on insulator (SOI), silicon carbide or a gallium arsenide substrate.

The semiconductor substrate may be doped or undoped with a suitable dopant material and it may contain one or more active device regions therein.

The integrated circuit chip comprises an insulating layer 101, which typically comprises an oxide as an insulating material.

Especially preferred are SOI-substrates which comprise n-type or p-type silicon wafers and a buried electrically insulating layer of SiO2 below the surface of the wafer.

The thickness of the buried oxide layer (insulating layer) is preferably between 0.3 and 3 μm and the thickness of the layer of monocrystalline silicon is between 0.1 and 4 μm.

Furthermore, the integrated circuit chip layer includes a first electrically conductive layer 102, which may be a polysilicon layer formed by doping polysilicon with impurities.

The integrated circuit chip may alternatively comprise as a first electrically conductive layer a layer of n-doped monocrystalline silicon.

Deposited on top of the first electrically conductive layer is a dielectric layer 103 composed of any dielectric material such as, but not limited to, SiO2, Si3N4, siliconoxynitride, glass, BPSG (Boron Doped Phospho-Silicate Glass), diamond-like carbon, parylene polymers, polyamides, silicon-containing polymers, and like dielectric materials.

The second electrically conductive layer 106, 107 is preferably made of sputtered aluminum which is preferred for its high electrical and thermal conductivity, low cost and compatibility with other semiconductor processes and materials. However, other sufficiently conductive materials may be used for layer 106, e.g. alloys based on aluminum, such as Al—Si—Cu alloy (Al: 98.5-97.5 wt %, Si: 1-2 wt %, Cu: 0.5 wt %).

Further preferred electrically conductive materials that can be employed in the present invention are metals and alloys that contain silver, gold, platinum, copper, tungsten, tantalum, titanium, and like conductive metals.

To avoid degradation of the integrated circuit chip, the structure is preferably further provided with a passivating layer which encapsulates the patterned semiconductor device, not shown.

In the present invention the integrated circuit chip device is voltage-protected by an electrostatic discharge protection device.

Referring to FIG. 1, an electrostatic discharge protection device according to the invention comprises a pair of center and circumferential electrodes, which are spaced apart such that they define a gas filled steroidal gap between them.

The spark discharge device further comprises a base layer and a top layer, which substantially surrounds the electrodes and the air gap, such that the air gap is hermetically sealed from the external environment. The air gap may comprise an inert gas.

As shown in the drawings, the electrostatic discharge protection device according to the invention thus has a quaternary-laminated structure comprising a lower insulating base layer 101, a middle electrically conductive layer 102 and a dielectric top layer 103. The middle electrically conductive layer 102 is interposed between the upper and lower layer 101 and 103, and has a steroidal discharge gap opening.

The fourth layer, i.e. the second electrically conductive layer, comprises a contact pad. Said contact pad fills the center of the opening and extends down to the first layer, forming a plug that hermetically seals the discharge gap 105.

The thickness of the disk-like circumferential electrode will depend on the level of protection sought and can be optimized using known experimental techniques so as to, for example, minimize at the electrodes the effects of spark induced erosion for the rated voltage. The steroidal spark gap opening is selected in such a way that its thickness and dielectric field strength in volts per centimeter of thickness of the dielectric layer will result in a sudden rupture of the dielectric layer at the desired high voltage threshold value. Thinner gaps have lower threshold voltages, and vice-versa.

The toroid of the spark gap cavity need not be of perfect ring shape, neither in cross section nor in horizontal projection, but may also resemble an ellipsoid or a regular or irregular polygon.

To prevent diffusion of second electrically conductive material into substrate layer 100, insulating layer 101 should have a thickness which will prevent the second electrically conductive material of layer 106 from migrating into layer 100.

The center and circumferential electrodes also include contact pads 106 and 107, respectively, which are positioned away from the central region of the electric discharge protection device, and by means of which electrical interconnections may be made to the device.

By contact pad 106 the center electrode is electrically connected to an input circuit path to be protected from electrostatic discharge and by contact pad 107 the circumferential electrode is electrically connected to an electrostatic discharge path comprising either a connection to a circuit ground or a circuit supply voltage.

The above-mentioned electrostatic discharge protection device of this invention is fabricated using the following process, which will be described in detail herein below in conjunction with the accompanying drawings FIGS. 2 to 6.

As the invention is directed to the lateral insulation between a first electrically conductive layer and a second electrically conductive layer by means of a steroidal air gap, these Figures show just this portion of the chip. It will be understood that these elements comprise a portion of a much larger integrated circuit chip.

The process of fabricating the electrostatic discharge protection device of this invention is preferably a planar technology process. When the electrostatic discharge device according to this invention is fabricated using a planar technology process as described above, it is possible to easily and simply produce desired electrostatic discharge devices at a low production cost.

Nevertheless, the active devices contained within the integrated circuit chip may be fabricated also by means of complementary metal oxide silicon (CMOS), RF CMOS, bipolar, BiCMOS, SiGe bipolar, silicon-germanium-carbon (SiGeC) and SiGe BiCMOS technologies.

It will be understood by those skilled in the art that the process steps described here require selective processing that can be achieved by well known photolithographic masking techniques, and standard etching, ion implantation, oxide growth or deposition as required, metal deposition and patterning, etc. These various process steps are sufficiently established in the IC wafer fabrication art that the details are unnecessary to the practice of the invention. Variations in the steps may be made, and steps may be omitted or substituted by other steps, without departing from the invention.

A method of fabricating an integrated circuit chip comprising an integrated circuit and an electrostatic discharge protection device according to the invention, includes the steps of a) providing a semiconductor substrate, b) depositing an insulating layer on the semiconductor substrate, c) depositing a first electrically conductive layer of a first electrically conductive material on said insulating layer, d) depositing a dielectric layer of a dielectric material on said first electrically conductive layer, e) etching spaced contact windows for a center electrode and a circumferential electrode, f) depositing a mask, g) etching a hollow groove into the first electrically conductive layer under the circumference of the contact window of the circumferential electrode, h) depositing a layer of a second electrically conductive layer through the contact window of the center electrode to mechanically contact the insulating layer, and through the contact window of the circumferential electrode to electrically contact the first electrically conductive layer, i) connecting the center electrode to input circuit paths to be protected from electrostatic discharge and connecting the circumferential electrode to an electrostatic discharge path comprising either a connection to a circuit ground or a circuit supply voltage.

Typically the process is started with a monocrystalline semiconductor, in particular a silicon wafer onto which a layer of oxide is grown.

According to one embodiment of the invention the manufacture of the circuit according to the invention begins with the production of the SOI substrate, i.e. with the formation of a silicon substrate 100, that is a monocrystalline layer of monosilicon, and of a buried insulating layer of oxide 101. The monocrystalline layer of monosilicon 100 and the insulating layer together form the silicon-on-insulator (SOI) substrate.

The SOI substrate can be produced by any of the conventional production processes. A successful process for producing high-quality SOI substrates is the SIMOX process. This is based on the high-dosage implantation of oxygen ions into weakly doped n-type or p-type silicon wafers to produce a buried, electrically insulating layer of SiO2 below the surface of the wafer.

The thickness of the insulating layer may be 0.5 to 1 μm.

With the insulating layer 101 in place, the first electrically conductive layer, which is preferably a polysilicon layer 102 is deposited over the structure.

Typically, the polysilicon layer is deposited by chemical vapor deposition (CVD) or plasma-enhanced CVD (PE-CVD), and is heavily n-type doped for an n-channel transistor. The layer thickness may be in the range 1-5 μm. If desired the polysilicon layer may be silicided by deposition of a tantalum, titanium, or tungsten layer, and heated to form the silicide.

This expedient, which is optional, is especially useful for high frequency RF devices as the one described here.

A dielectric layer 103 is deposited over the entire structure. Layer 103 may be any suitable, deposited thin film dielectric material such as silicon oxide (SixOy), silicon nitride (SixNy) or preferably siliconoxynitride (SiOxNy). Layer 103 may range in thickness from about 0.3 to 2.5 microns depending in part on the combined thickness of layers 102 and 101, and is preferably about 0.6 micron thick for the typical thicknesses of layers 101 and 102.

The dielectric layer is formed using conventional deposition processes such as chemical vapor deposition, plasma-assisted chemical vapor deposition, spin-on coating, sputtering, and like deposition processes.

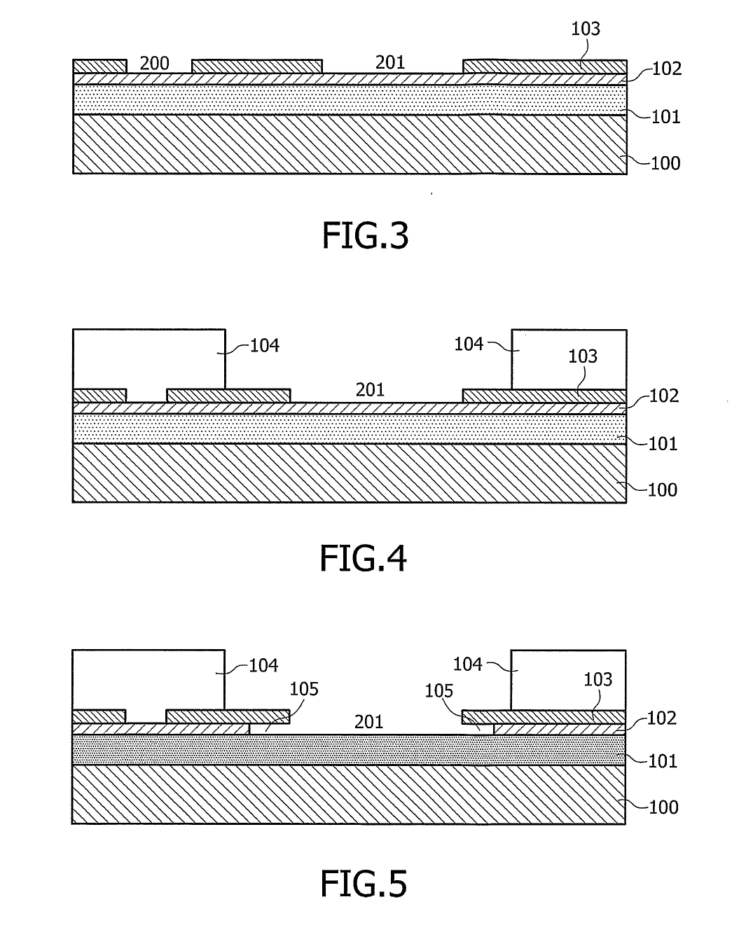

The dielectric layer 103 is masked with a lithographic mask, and patterned by conventional etching to define windows 200, 201 as shown in FIG. 3. The mask may be a standard photoresist, but is preferably an oxide hard mask formed by TEOS deposition and standard photoresist patterning.

As shown in FIG. 4, subsequently a layer of photoresist 104 is deposited on top of insulating layer 103, and exposed and developed so as to create a suitable mask to give access to the opening 201 in layer 103. As shown in FIG. 5, subsequently layer 102 is etched with suitable solvent or dry etchant to form an undercut in layer 102 under opening 201 in layer 103.

Such under-cuttings in polysilicon can be produced by isotropic dry etching processes, such as reactive ion etching using fluorine-containing gases, as is well known in the art.

Then the photoresist mask 104 is removed. Next, an electrode-forming second electrically conductive layer is deposited over the patterned layers 102 and 103.

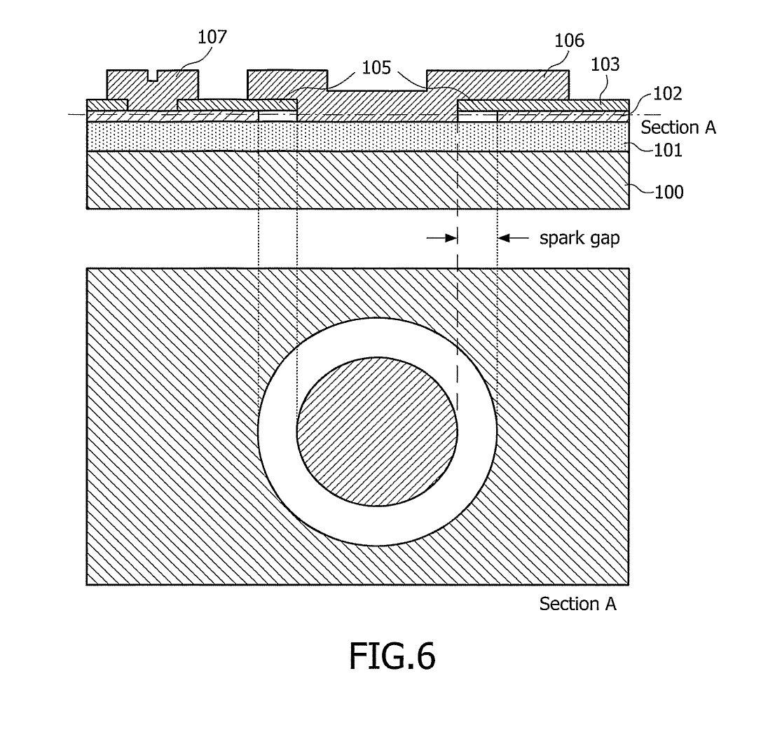

As shown in FIG. 6, 106, 107, the second electrically conductive layer is directionally sputtered onto the substrate so as to deposit electrode material on top of the dielectric layer 103 and on a surface portion of the insulating layer 101, without depositing much of any electrode material into the undercutting 105.

The electrode-forming second electrically conductive layer may be deposited using any conventional or suitable technique such as sputtering, evaporation, vapor deposition, or the like. Preferably, the electrode layer is deposited by cathodic sputtering in an inert gas atmosphere.

Thereby, the open space of the undercutting is filled with gas, normally argon, to avoid effects caused by humidity or variations in gas density, which would affect the overvoltage of the electric discharge protection device.

The contact pad 106 of the center electrode is in intimate contact with the insulation layer 101 at the interface there between, and with dielectric layer 103 at interface 50 between top metallization and second insulation layer.

The second electrically conductive layer is subsequently subjected to an isotropic wet etch to form electrode contact pads 106 and 107.

Contact pads 106,107 will be connected to an input circuit path and an electrostatic discharge path on the same substrate or to terminal pads (not shown). The etching of the various thin film layers of these structures may be accomplished using conventional or suitable etchants, either wet or dry, known to those skilled in the art.

The thickness of the various layers used in the ESD protection structure, as well as the other structures of the present invention, may be readily controlled using any one of several techniques well known in the art. Those skilled in the art will readily appreciate that the threshold voltage of the electrostatic discharge protection device may be made much higher or much lower simply by increasing or decreasing the thickness of the semiconductor layer 102.

In operation, the spark gap toroid dissipates a portion of the transient energy of an electrostatic discharge event by allowing electrostatic discharge current to arc from input center electrode pad 106 to ground supply circumferential electrode through spark gap cavity 105.

The variety of configurations available for the overvoltage protection devices of the present invention, together with their small size and generally planar construction, allows the devices to be tailored to have a preselected impedance by controlling resistance, capacitance and inductance. Thus, the devices of the present invention, when appropriately scaled in size, are particularly well suited for use in connection with microelectronic circuit applications where large capacitances are to be avoided.

For any of the above circuits and applications there are advantages in having an on-chip electrostatic discharge protection device. An on-chip electrostatic discharge protection device has a lower series resistance and lower inductance. This is especially important when an integrated circuit has a very high output current and/or multiple outputs that can simultaneously dump current. The change in current with respect to time created by simultaneous output switching can cause a significant change in voltage with respect to time in the inductance of the bond wires and package leads of the power supply pins. Such change in voltage with respect to time causes a reduction of the effective power supply voltage for a short period of time. If the integrated circuit had memory elements present on it, the state of those memory elements could be erroneously altered, especially if the power supply voltage dropped too low. An on-chip electrostatic discharge protection device would help prevent such unwanted memory losses.

### NUMERALS

100 substrate
101 insulating layer
102 first electrically conductive layer
103 dielectric layer
104 photo resist
105 spark gap cavity
106 electrode
107 ground electrode
200 contact window of ground electrode
201 contact window

1. An integrated circuit chip comprising, in sequence,
a substrate layer of a substrate material,
an insulating layer of an insulating material,
a first electrically conductive layer of a first electrically conductive material,
a dielectric layer of a dielectric material and
a second electrically conductive layer of a second electrically conductive material,
said IC chip comprising at least one integrated circuit and at least one integrated electrostatic discharge protection device, said electrostatic discharge protection device comprising,
a pair of spaced center and circumferential electrodes, the center electrode being formed by the first electrically conductive layer and the circumferential electrode being formed by the second electrically conductive layer, said electrodes being separated by a steroidal spark gap cavity, wherein the toroid of the steroidal spark gap cavity comprises,
a base layer formed by the insulating layer of the integrated circuit chip,
a side wall formed by the circumferential electrode,
a cover layer formed by the dielectric layer of the integrated circuit chip, and the center of the toroid being formed by the center electrode comprising a contact pad in contact with the insulating layer,
said electrostatic discharge protection device also comprising means to electrically connect the center electrode to input circuit paths to be protected from electrostatic discharge and means to electrically connect the circumferential electrode to an electrostatic discharge path comprising either a connection to a circuit ground or a circuit supply voltage.

2. The integrated circuit chip of claim 1, further comprising a passive component selected from the group comprising resistors, capacitors, and inductors.

3. The integrated circuit chip of claim 1, wherein the first electrically conductive material is polysilicon.

4. The integrated circuit chip of claim 1, wherein the second electrically conductive material is aluminum.

5. The integrated circuit chip of claim 1, wherein the spark gap cavity contains a noble gas for reducing the breakdown voltage of the electrostatic discharge protection device.

6. The integrated circuit chip of claim 1, wherein the substrate material is selected from the group comprising silicon, glass and a ceramic material.

7. A method of fabricating an integrated circuit chip comprising an integrated circuit and an electrostatic discharge protection device comprising the steps of
a) providing a semiconductor substrate,
b) depositing an insulating layer on semiconductor substrate,
c) depositing a first electrically conductive layer of a first electrically conductive material on said insulating layer,
d) depositing a dielectric layer of a dielectric material on said first electrically conductive layer,
e) etching spaced contact windows for a center electrode and a circumferential electrode,
f) depositing a mask,
g) etching a hollow groove into the first electrically conductive layer under the circumference of the contact window of the circumferential electrode,
h) depositing a layer of a second electrically conductive layer through the contact window of the center electrode to mechanically contact the insulating layer, and through the contact window of the circumferential electrode to electrically contact the first electrically conductive layer, and
i) connecting the center electrode to input circuit paths to be protected from electrostatic discharge and connecting the circumferential electrode to an electrostatic discharge path comprising either a connection to a circuit ground or a circuit supply voltage.
